(19) United States
(12) Patent Application Publication
(10) Pub. No.: US 2022/0006051 A1
(43) Pub. Date: Jan. 6, 2022

(54) DISPLAY DEVICE

(71) Applicant: SHARP KABUSHIKI KAISHA, Sakai City, Osaka (JP)

(72) Inventors: JUMPEI TAKAHASHI, Sakai City, Osaka (JP); TOHRU SONODA, Sakai City, Osaka (JP); TAKASHI OCHI, Sakai City, Osaka (JP); AKIHIRO MATSUI, Sakai City, Osaka (JP); TOHRU SENOO, Sakai City, Osaka (JP); TAKESHI HIRASE, Sakai City, Osaka (JP); HIDEKI NAKADA, Yonago-shi, Tottori (JP); TSUYOSHI SENZAKI, Yonago-shi, Tottori (JP)

(21) Appl. No.: 17/280,845

(22) PCT Filed: Sep. 27, 2018
(86) PCT No.: PCT/JP2018/036060

§ 371 Date: Mar. 26, 2021

(51) Int. Cl. H01L 51/52; H01L 27/32; H01L 51/56

(52) U.S. Cl. CPC H01L 51/5253; H01L 2227/323; H01L 51/56; H01L 27/3276

(57) ABSTRACT

A display device includes a display region in which a plurality of light-emitting elements are disposed, each of which is provided with a first electrode, a second electrode, and a function layer formed between the first electrode and the second electrode. The display device includes a frame region surrounding the display region, and a sealing layer. The second electrode includes an extending portion extending from the display region to the frame region, and overlaps all of the display region. A cap layer is provided on the extending portion so as to overlap at least part of an end portion of the extending portion, and the cap layer overlaps all of the display region. The sealing layer overlaps all of the second electrode and all of the cap layer.

### TECHNICAL FIELD

The present invention relates to a display device.

### BACKGROUND ART

In recent years, various display devices have been developed. Particularly, a display device including an organic light-emitting diode (OLED) and a display device including an inorganic light-emitting diode or a quantum dot light-emitting diode (QLED) have drawn a great deal of attention because these devices are capable of achieving lower power consumption, smaller thickness, higher picture quality, and the like.

For example, in the field of display devices provided with OLEDs, QLEDs, and the like, PTL 1 describes manufacturing of a display device using a vapor deposition mask capable of patterning a vapor deposition film with a higher precision in order to realize a display device of a higher resolution.

### CITATION LIST

### Patent Literature

PTL 1: JP 2018-59139 A (published Apr. 12, 2018).

### SUMMARY OF INVENTION

### Technical Problem

However, even in the case where the vapor deposition mask capable of patterning the vapor deposition film with a high precision as described in PTL 1 is used, dust may become adhered to the vapor deposition mask, or a cleaning liquid for the vapor deposition mask may remain in the vapor deposition mask.

When forming the vapor deposition film using the vapor deposition mask, contaminants, such as dust and a cleaning liquid adhered to the vapor deposition mask in this manner, may be transferred to an active matrix substrate side on which the vapor deposition film is formed. Due to the contaminant that has been transferred to the active matrix substrate side in this manner, for example, when plasma treatment is performed on a film that has been formed in a post process after a process of forming the vapor deposition film using the vapor deposition mask, the film formed on the contaminant may be affected by the contaminant, and film peeling or the like may occur.

The present invention has been conceived in light of the problem described above, and an object thereof is to provide a display device capable of preventing film peeling or the like from occurring due to a contaminant.

### Solution to Problem

In order to solve the problem described above, a display device according to the present invention includes a display region in which a plurality of light-emitting elements are disposed, a frame region surrounding the display region, and a sealing layer, each of the light-emitting elements being provided with a first electrode, a second electrode formed above the first electrode, and a function layer formed between the first electrode and the second electrode. The second electrode includes an extending portion extending from the display region to the frame region, and overlaps all of the display region. A cap layer is provided above the extending portion to overlap at least part of an end portion of the extending portion, and the cap layer overlaps all of the display region. The sealing layer overlaps all of the second electrode and all of the cap layer.

### Advantageous Effects of Invention

According to an aspect of the present invention, it is possible to provide a display device capable of preventing film peeling or the like from occurring due to a contaminant.

### BRIEF DESCRIPTION OF DRAWINGS

FIG. 1(a) is a diagram illustrating a schematic configuration of a display device according to a first embodiment, FIG. 1(b) is a diagram illustrating a drive circuit provided in the display device according to the first embodiment, and also illustrating a display region, a formation region of a second electrode including an extending portion, and a formation region of a cap layer in an active matrix substrate.

FIG. 2(a) is a diagram illustrating a case where a mask is disposed on the active matrix substrate, FIG. 2(b) is an enlarged partial view of a portion A illustrated in FIG. 2(a), and FIG. 2(c) is a side view of the mask illustrated in FIG. 2(a).

FIG. 3 is a diagram illustrating the active matrix substrate and the mask illustrated in (a) of FIG. 2.

FIG. 4 is a diagram illustrating a cross section of a side, which is a drive circuit side, of the active matrix substrate in which the second electrode including the extending portion and the cap layer are formed.

FIG. 5(a) is a diagram illustrating a cross section of a portion other than the side, which is the drive circuit side, of the active matrix substrate in which the second electrode including the extending portion and the cap layer are formed, and FIG. 5(b) is a diagram illustrating a case where the active matrix substrate illustrated in (a) of FIG. 5 includes a contaminant.

FIG. 6 is a diagram illustrating the display region, the formation region of the second electrode including the extending portion, and the formation region of the cap layer in an active matrix substrate provided in a display device, which is a modified example of the first embodiment.

FIG. 7(a) is a plan view of a mask including a mask sheet and a hauling sheet, and FIG. 7(b) is a side view of the mask illustrated in FIG. 7(a).

FIG. 8(a) is a diagram illustrating a case where a mask is disposed on an active matrix substrate, FIG. 8(b) is an enlarged partial view of a portion B illustrated in FIG. 8(a), and FIG. 8(c) is a side view of the mask illustrated in FIG. 8(a).

FIG. 9 is a diagram illustrating the drive circuit provided in a display device according to a second embodiment, and illustrating the display region, the formation region of the second electrode including the extending portion, and the formation region of the cap layer in the active matrix substrate.

FIG. 10(a) is a diagram illustrating a region in which a frame region is large in the display device according to the second embodiment, and FIG. 10(b) is a diagram illustrating a region in which the frame region is small in the display device according to the second embodiment.

### DESCRIPTION OF EMBODIMENTS

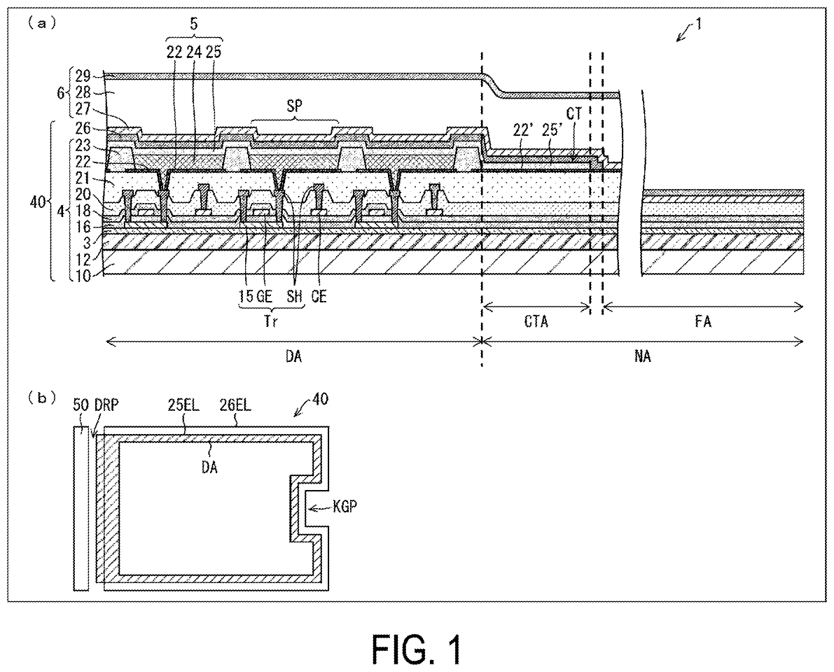

A description follows regarding embodiments of the present invention, with reference to FIG. 1 to FIG. 10. Hereinafter, for convenience of description, components having the same functions as those described in a specific embodiment are denoted by the same reference numerals, and descriptions thereof may be omitted.

### First Embodiment

(a) of FIG. 1 is a diagram illustrating a schematic configuration of a display device 1 according to a first embodiment, (b) of FIG. 1 is a diagram illustrating a drive circuit 50 provided in the display device 1, and also illustrating a display region DA, a formation region of a second electrode 25 including an extending portion 25′, and a formation region of a cap layer 26 in an active matrix substrate 40.

In the present embodiment, a case will be described as an example where an active matrix substrate 4 having a configuration described below is used, but the substrate is not particularly limited to this example, as long as the substrate includes an active element such as a thin film transistor element (a TFT element).

The active matrix substrate 4 illustrated in (a) of FIG. 1 includes a substrate 10, a resin layer 12, a barrier layer (base coat film) 3 that is an inorganic film, an inorganic insulating film 16, an inorganic insulating film 18, an inorganic insulating film 20, and an interlayer insulating film 21.

Then, in the display region DA of the active matrix substrate 4, a plurality of TFT elements Tr are formed each including a semiconductor film 15, the inorganic insulating film 16, a gate electrode GE, the inorganic insulating film 18, the inorganic insulating film 20, and a source and drain wiring line SH. Further, in the display region DA of the active matrix substrate 4, a plurality of capacitance elements are formed each including a capacitance electrode (not illustrated) included in a capacitance wiring line CE formed directly above the inorganic insulating film 18, the inorganic insulating film 18, and a capacitance counter electrode (not illustrated) formed directly below the inorganic insulating film 18 and formed overlapping the capacitance electrode in the same layer as a layer forming the gate electrode GE.

Further, in the display region DA of the active matrix substrate 4, a first electrode 22 is formed in an upper layer overlying the interlayer insulating film 21, and a bank 23 is formed covering an edge of the first electrode 22. In addition, a lead portion 22′ is formed in the same layer as the first electrode 22 so as to extend across the display region DA and a frame region NA of the active matrix substrate 4.

In the present embodiment, three layers of a hole transport layer, a light-emitting layer, and an electron transport layer are formed on the first electrode 22 as a function layer 24, but no such limitation is intended, and layers other than the light-emitting layer, namely, the hole injection layer, the hole transport layer, the electron transport layer, and an electron injection layer may be omitted as appropriate, or the function layer 24 may be formed over the entire surface of the display region DA, without patterning the layer in a region SP within the bank 23 using a vapor deposition mask.

As illustrated in (a) of FIG. 1, the active matrix substrate 40 includes the cap layer 26 formed covering the second electrode 25 formed over the entire surface of the display region DA and the extending portion 25′ of the second electrode 25.

In the display device 1 illustrated in (a) of FIG. 1, after performing the plasma treatment for forming the sealing layer 6 at least on the cap layer 26, the sealing layer 6 is formed.

The sealing layer 6 is light-transmissive and includes a first inorganic sealing film 27, an organic sealing film 28 formed above the first inorganic sealing film 27, and a second inorganic sealing film 29 covering the organic sealing film 28. The sealing layer 6 that seals the light-emitting element layer 5 prevents water, oxygen and the like from penetrating the light-emitting element layer 5.

Each of the first inorganic sealing film 27 and the second inorganic sealing film 29 may be formed, for example, of a silicon oxide film, a silicon nitride film, or a silicon oxynitride film, or of a layered film of these, formed by CVD. The organic sealing film 28 is thicker than the first inorganic sealing film 27 or the second inorganic sealing film 29, is a light-transmitting organic film, and can be formed of a coatable photosensitive organic material such as a polyimide resin or an acrylic resin.

In the present embodiment, a case has been described as an example where the sealing layer 6 is formed by a layered body formed by three layers, but the sealing layer 6 is not limited to this example, and the sealing layer 6 may be formed by a single layer of the first inorganic sealing film 27, or by a layered body formed by five or more layers of an organic sealing film and an inorganic sealing film.

As illustrated in (a) of FIG. 1, the frame region NA of the display device 1 includes a contact region CTA in which the lead portion 22′ and the extending portion 25′ of the second electrode 25 form a contact portion CT, and a sealing region FA outside an end portion of the cap layer 26.

Examples of the substrate 10 include a glass substrate having high heat resistance, but are not limited thereto.

Examples of the material of the resin layer 12 include a polyimide resin, an epoxy resin, and a polyamide resin, but are not limited thereto.

The barrier layer 3 is a layer that prevents moisture or impurities from reaching the TFT element Tr or the function layer 24 and can be formed, for example, of a silicon oxide film, a silicon nitride film or a silicon oxynitride film, or of a layered film of these films, formed by CVD.

The semiconductor film 15 is formed of low-temperature polysilicon (LTPS) or an oxide semiconductor, for example.

The gate electrode GE, the capacitance wiring line CE, and the source and drain wiring line SH are each formed of a single layer film or a layered film of metal, the metal including at least one of aluminum (Al), tungsten (W), molybdenum (Mo), tantalum (Ta), chromium (Cr), titanium (Ti), copper (Cu), and silver (Ag), for example.

The inorganic insulating films 16, 18, and 20 may each be formed, for example, of a silicon oxide (SiOx) film, a silicon nitride (SiNx) film, or a silicon oxynitride film, or of a layered film of these, formed by CVD.

The interlayer insulating film 21 may be formed, for example, of a coatable photosensitive organic material, such as a polyimide resin and an acrylic resin.

The first electrode (anode electrode) 22 can be formed by layering indium tin oxide (ITO) and an alloy including silver (Ag), and has light reflectivity.

The bank 23 can be formed, for example, of a coatable photosensitive organic material, such as a polyimide resin and an acrylic resin.

In the present embodiment, a case has been described as an example where the substrate 10 provided in the display device 1 is a glass substrate having high heat resistance, but no such limitation is intended. For example, the disclosure may be applied to a flexible display device that is obtained by irradiating the resin layer 12 with laser light through the substrate 10 provided in the display device 1, then peeling off the substrate 10 from the resin layer 12, and using the resin layer 12 as a flexible substrate. Furthermore, the flexible display device may be obtained by attaching a flexible substrate to a surface of the resin layer 12 from which the substrate 10 has been peeled off.

(b) of FIG. 1 is a diagram illustrating the drive circuit 50 provided in the display device 1, and also illustrating the display region DA, the formation region of the second electrode 25 including the extending portion 25′, and the formation region of the cap layer 26 in the active matrix substrate 40.

As illustrated in (b) of FIG. 1, a notched portion is provided in the display region DA of the active matrix substrate 40 included in the display device 1. Then, an end portion 25EL of the extending portion 25′ includes a first notched region KGP, of the extending portion 25′, formed along the notched portion. The cap layer 26 is formed covering all of the first notched region KGP of the extending portion 25′. Note that, as indicated by diagonal lines in (b) of FIG. 1, the extending portion 25′ of the second electrode 25 illustrated in (a) of FIG. 1 is, of the second electrode 25, a part of the second electrode 25 that is disposed in a region other than the display region DA.

Further, as illustrated in (b) of FIG. 1, on a side DRP, which is the drive circuit 50 side, of the extending portion 25′, the second electrode 25 including the extending portion 25′ and the cap layer 26 are formed so that the end portion 25EL of the extending portion 25′ is positioned closer to the drive circuit 50 than an end portion 26EL of the cap layer 26.

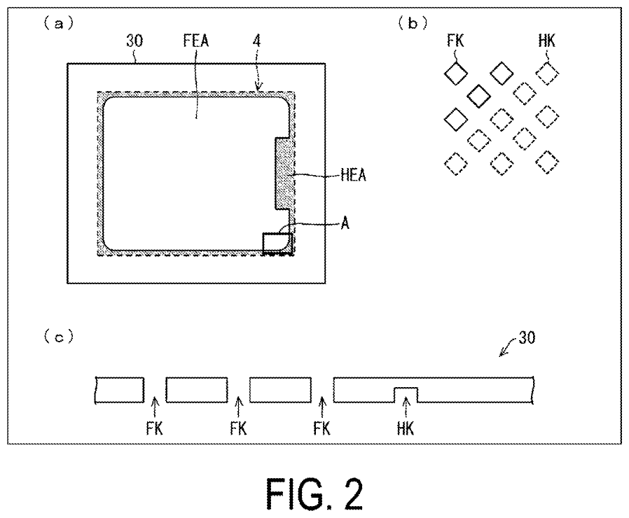

(a) of FIG. 2 is a diagram illustrating a case where a mask 30 is disposed on the active matrix substrate 4, (b) of FIG. 2 is an enlarged partial view of a portion A illustrated in (a) of FIG. 2, and (c) of FIG. 2 is a side view of the mask 30 illustrated in (a) of FIG. 2.

As illustrated in (a) of FIG. 2, a vapor deposition film is formed on the active matrix substrate 4 in a state in which the mask 30 is disposed on the active matrix substrate 4 indicated by a dotted line. The mask 30 is a fine metal mask (FMM) sheet. The mask 30 includes a mask opening formation region FEA and a mask recess formation region HEA. As illustrated in (b) of FIG. 2 and (c) of FIG. 2, a plurality of mask openings FK, which are through-holes for allowing vapor deposition particles to pass through, are formed in the mask opening formation region FEA, and a plurality of mask recesses HK, which are non-through-holes, are formed in the mask recess formation region HEA.

As illustrated in (a) of FIG. 2, when a corner portion or a notched portion having a curved shape is incorporated in the mask opening formation region FEA, the mask 30 easily becomes distorted when the mask 30 is stretched. Thus, by incorporating the mask recess formation region HEA in the mask 30, the distortion that occurs when the mask 30 is stretched is suppressed.

As illustrated in (a) of FIG. 2, a region of the mask 30 facing the display region of the active matrix substrate 4 is the mask opening formation region FEA, and a region of the mask 30 facing the frame region of the active matrix substrate 4 is the mask recess formation region HEA.

Note that although only the one mask opening formation region FEA and the one mask recess formation region HEA, each corresponding to the one active matrix substrate 4, are illustrated in the mask 30 illustrated in (a) of FIG. 2, no such limitation is intended, and the mask 30 may include a plurality of the mask opening formation regions FEA and a plurality of the mask recess formation regions HEA corresponding to a plurality of the active matrix substrates 4.

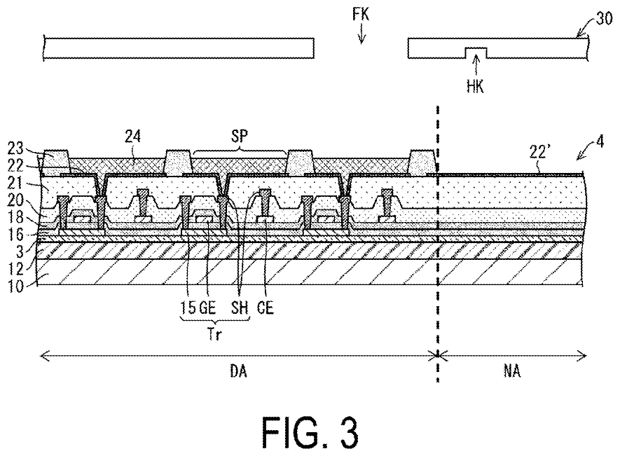

FIG. 3 is a diagram illustrating the active matrix substrate 4 and the mask 30 illustrated in (a) of FIG. 2.

For example, in some cases, a contaminant such as dust or a cleaning liquid for the mask may become adhered to or remain in the mask recess HK, which is the non-through-hole in the mask 30. When forming the function layer 24 using the mask 30, such a contaminant may be transferred to the active matrix substrate 4 side on which the function layer 24 is formed, and may become a contaminant on the active matrix substrate 4. Due to the contaminant on the active matrix substrate 4, for example, when the plasma treatment is performed on the second electrode 25 including the extending portion 25′, which is a film formed in a post process after a process of forming the function layer 24 using the mask 30, the second electrode 25 including the extending portion 25′ formed on the contaminant may be affected by the contaminant, and film peeling or the like may occur.

The mask 30 illustrated in FIG. 3 is a mask for patterning the function layer 24 via the mask openings FK, which are the through-holes for allowing the vapor deposition particles to pass through.

The function layer 24 illustrated in FIG. 3 is included in each of subpixels that emit red light, green light, and blue light, respectively, from the left side in the drawing, for example. The function layer 24 included in the red sub-picture element is formed using a mask (not illustrated) for forming the function layer 24 included in the red sub-picture element, and the function layer 24 included in the green sub-picture element is formed using a mask (not illustrated) for forming the function layer 24 included in the green sub-picture element. Then, the function layer 24 included in the blue sub-picture element is formed using the mask 30 including the opening FK for forming the function layer 24 included in the blue sub-picture element.

Note that the function layer 24 is the layer including at least one of the hole injection layer, the hole transport layer, the light-emitting layer, the electron transport layer, and the electron injection layer, and refers to a vapor deposition film that is patterned in the region SP within the bank 23 using a vapor deposition mask.

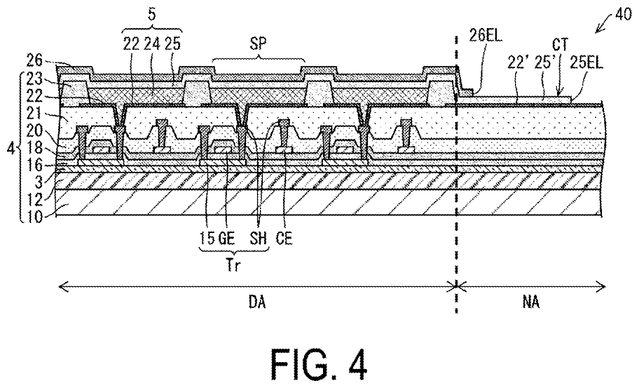

FIG. 4 is a diagram illustrating a cross section of the side DRP, which is the drive circuit 50 side, of the active matrix substrate 40 in which the second electrode 25 including the extending portion 25′ and the cap layer 26 are formed.

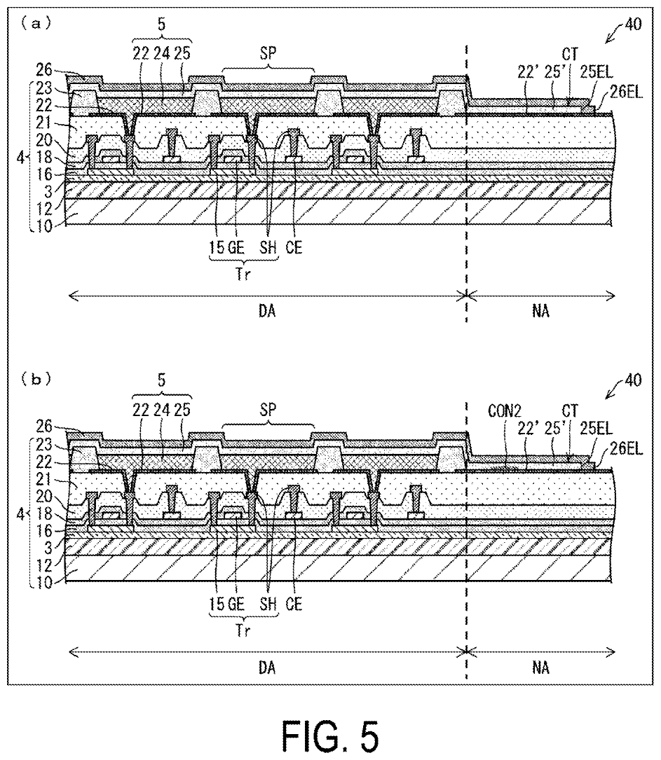

(a) of FIG. 5 is a diagram illustrating a cross section of a portion other than the side DRP, which is the drive circuit 50 side, of the active matrix substrate 40 in which the second electrode 25 including the extending portion 25′ and the cap layer 26 are formed, and (b) of FIG. 5 is a diagram illustrating a case where the active matrix substrate 40 illustrated in (a) of FIG. 5 includes a contaminant CON2.

As illustrated in FIG. 4 and FIG. 5, the second electrode 25 is formed over the entire surface of the display region DA of the active matrix substrate 40 so as to cover the banks 23 and the function layer 24. Then, the extending portion 25′ of the second electrode 25 is formed on the side DRP, which is the drive circuit 50 side, of the active matrix substrate 40 and also in the frame region NA on the sides other than the side DRP, which is the drive circuit 50 side, so as to form the lead portion 22′ and the contact portion CT.

On the side DRP, which is the drive circuit 50 side, of the active matrix substrate 40 illustrated in FIG. 4, the second electrode 25 and the cap layer 26 are formed so that the end portion 26EL of the cap layer 26 is positioned closer to the display region DA side than the end portion 25EL of the extending portion 25′, for example, in consideration of an electrical connection with the drive circuit 50 (see (b) of FIG. 1) and the like. Therefore, a portion of the extending portion 25′ is exposed without being covered by the cap layer 26.

On the other hand, on the sides other than the side DRP, which is the drive circuit 50 side, of the active matrix substrate 40, which are illustrated in (a) of FIG. 5 and (b) of FIG. 5, the cap layer 26 is formed overlapping the end portion 25EL of the extending portion 25′. In other words, the cap layer 26 is formed covering the extending portion 25′. Therefore, as illustrated in (b) of FIG. 5, even when the active matrix substrate 40 includes the contaminant CON2, it is possible to prevent the extending portion 25′ formed on the contaminant CON2 from being affected by the contaminant CON2 and causing film peeling or the like.

Further, this cap layer 26 is provided covering the entire surface of the display region DA, and is provided on the display device 1 as an optical adjustment member for adjusting light emitted from the light-emitting element 5. Therefore, for the cap layer 26, a material that can minimize a deterioration in brightness, light-emission characteristics, and the like of the light from the light-emitting element 5 is used.

On the sides other than the side DRP, which is the drive circuit 50 side, of the active matrix substrate 40, which are illustrated in (a) of FIG. 5 and (b) of FIG. 5, the plasma treatment for forming the sealing layer 6 (see (a) of FIG. 1) is performed on the cap layer 26 that is formed covering the extending portion 25′ instead of being performed on the extending portion 25′. Therefore, when the plasma treatment is performed on the second electrode 25 including the extending portion 25′, which is a relatively thin film, it is possible to prevent the extending portion 25′ formed on the contaminant CON2 from being affected by the contaminant CON2 and causing the film peeling or the like.

The second electrode 25 including the extending portion 25′ can be formed of a light-transmitting conductive material such as indium tin oxide (ITO) and indium zinc oxide (IZO), for example.

The light-emitting element 5 includes the first electrode 22, the function layer 24, and the second electrode 25. In the present embodiment, a case has been described as an example where the first electrode 22 is a light-reflective anode electrode, the second electrode 25 is a light-transmitting cathode electrode, and the light-emitting element 5 is a top-emitting type, but no such limitation is intended, and the first electrode 22 may be a light-transmissive cathode electrode, the second electrode 25 may be a light-reflective anode electrode, and the light-emitting element 5 may be a bottom-emitting type.

The cap layer 26 may be formed by a single layer, and when the cap layer 26 is formed by a single layer of an organic film, the cap layer 26 may be formed by a film containing aromatic hydrocarbon. Note that the aromatic hydrocarbon in the film containing the aromatic hydrocarbon may be N,N′-di-1-naphthyl-N,N′-diphenylbenzidine (also referred to as α-NPD or NPB). On the other hand, when the cap layer 26 is formed by a single layer of an inorganic film, the cap layer 26 may be formed by a LiF film. Furthermore, the cap layer 26 may be formed by a layered body of an organic film and an inorganic film. When the cap layer 26 is formed by the layered body of the organic film and the inorganic film, the organic film may be the film containing the aromatic hydrocarbon, and the inorganic film may be the LiF film.

Further, as in the present embodiment, when the cap layer 26 is formed by the layered body of the organic film and the inorganic film, a refractive index of the organic film in a visible light region is preferably higher than a refractive index of the inorganic film in the visible light region, and it is more preferable that the refractive index of the organic film in the visible light region be from 1.8 to 2.1, and the refractive index of the inorganic film in the visible light region be from 1.2 to 1.3.

Further, when the cap layer 26 is formed by the layered body of the organic film and the inorganic film, the film thickness of the organic film is preferably greater than the film thickness of the inorganic film, and it is more preferable that the film thickness of the organic film be from 50 nm to 100 nm, and the film thickness of the inorganic film be from 10 nm to 30 nm.

In the display device 1 according to the present embodiment, as illustrated in (b) of FIG. 1, since, in the extending portion 25′, the cap layer 26 is formed covering the extending portion 25′ on all the sides other than the side DRP of the extending portion 25′, which is the drive circuit 50 side, it is possible to prevent the contaminant CON2 from causing the film peeling or the like.

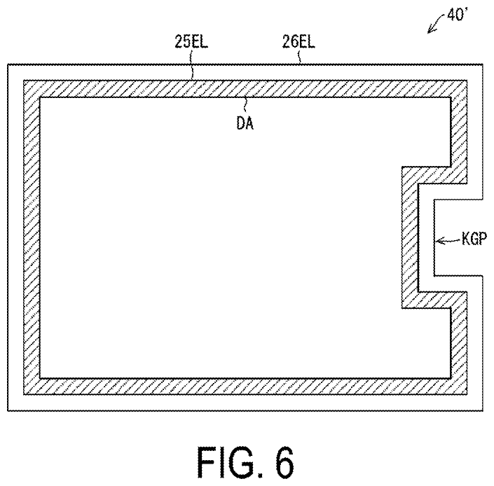

FIG. 6 is a diagram illustrating the display region DA, the formation region of the second electrode 25 including the extending portion 25′, and the formation region of the cap layer 26 in an active matrix substrate 40′ provided in a display device, which is a modified example of the first embodiment.

When it is not necessary to expose the portion of the extending portion 25′ in consideration of the electrical connection with the drive circuit 50 and the like, the cap layer 26 may be formed overlapping all of the second electrode 25 including the extending portion 25′, as in the active matrix substrate 40′ illustrated in FIG. 6. When the display device is provided with the active matrix substrate 40′, since all of the extending portion 25′ is covered by the cap layer 26, it is possible to more reliably prevent the contaminant CON2 from causing the film peeling or the like.

### Second Embodiment

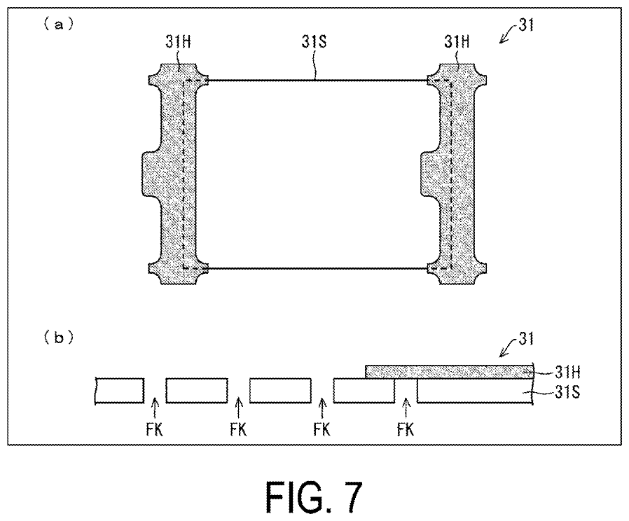

Next, a description will be given of a second embodiment of the present invention with reference to FIG. 7 to FIG. 10. The present embodiment differs from the first embodiment in that a region in which the cap layer 26 is formed covering the extending portion 25′ is reduced compared to that of the first embodiment described above, in order to achieve frame narrowing of the display device, and other configurations of the present embodiment are the same as those described in the first embodiment. For convenience of description, members having the same functions as those of the members illustrated in the diagrams in the first embodiment are denoted by the same reference signs, and a description thereof will be omitted.

(a) of FIG. 7 is a plan view of a mask 31 including a mask sheet 31S and a hauling sheet 31H, and (b) of FIG. 7 is a side view of the mask 31 illustrated in (a) of FIG. 7.

Even when using the mask 31 illustrated in FIG. 7, the same problem occurs as in the case of using the mask 30 illustrated in FIG. 2 and FIG. 3.

In the mask 31, for example, contaminants such as dust or cleaning liquid for the mask may become adhered to or remain in a portion at which the hauling sheet 31H overlaps the mask opening FK, which is a through-hole in the mask sheet 31S, in the same manner as in the mask recess HK, which is the non-through-hole in the mask 30 illustrated in FIG. 2 and FIG. 3.

In the mask 31, the portion at which the hawling sheet 31H overlaps the mask opening FK, which is the through-hole in the mask sheet 31S, that is, a portion corresponding to the mask recess HK, which is the non-through-hole in the mask 30 illustrated in FIG. 2 and FIG. 3, is reduced compared to that of the mask 30.

In the mask 31, in a portion of the active matrix substrate facing a portion of the mask 31 other than the portion at which the hauling sheet 31H overlaps the mask opening FK, which is the through-hole in the mask sheet 31S, it is not necessary to form the cap layer 26 to cover the extending portion 25′.

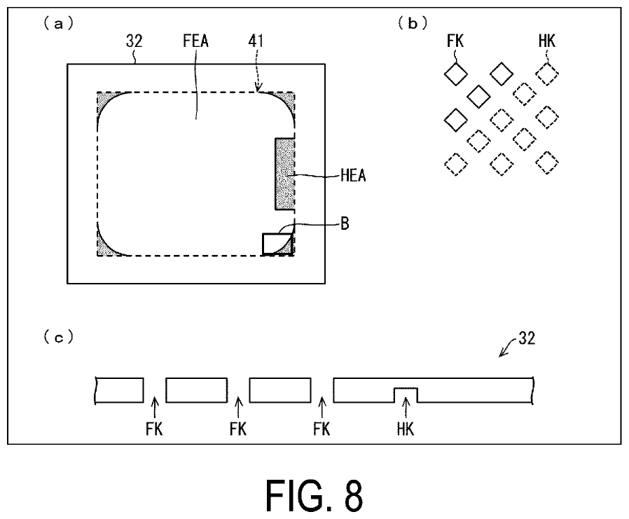

(a) of FIG. 8 is a diagram illustrating a case where a mask 32 is disposed on an active matrix substrate 41, FIG. 8(b) is an enlarged partial view of a portion B illustrated in (a) of FIG. 8, and (c) of FIG. 8 is a side view of the mask 32 illustrated in (a) of FIG. 8.

As illustrated in (a) of FIG. 8, a vapor deposition film is formed on the active matrix substrate 41 in a state in which the mask 32 is disposed on the active matrix substrate 41 indicated by a dotted line. The mask 32 is a fine metal mask (FFM) sheet. The mask 32 includes the mask opening formation region FEA and the mask recess formation region HEA. As illustrated in (b) of FIG. 8 and (c) of FIG. 8, the plurality of mask openings FK, which are the through-holes for allowing the vapor deposition particles to pass through, are formed in the mask opening formation region FEA, and the plurality of mask recesses HK, which are the non-through-holes, are formed in the mask recess formation region HEA.

As illustrated in (a) of FIG. 8, when a corner portion or a notched portion having a curved shape is incorporated in the mask opening formation region FEA, the mask 32 is easily distorted when the mask 32 is stretched. Thus, by incorporating the mask recess formation region HEA only in a portion of the mask 32 in which the corner portion or the notched portion having the curved shape is incorporated, the distortion that occurs when the mask 32 is stretched is suppressed. Therefore, in the mask 32, compared to the mask 30 illustrated in FIG. 2 and FIG. 3, the formation region of the mask recesses HK, which are the non-through-holes, is reduced.

In the mask 32, in a portion of the active matrix substrate facing a portion of the mask 32 other than the portion in which the mask recesses HK, which are the non-through-holes, are formed, it is not necessary to form the cap layer 26 to cover the extending portion 25′.

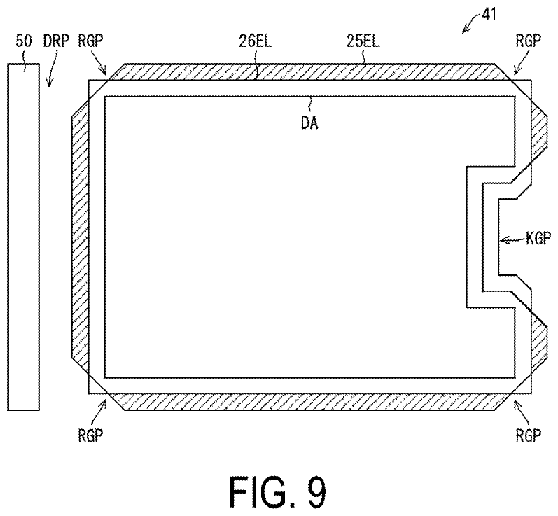

FIG. 9 is a diagram illustrating the drive circuit 50 provided in the display device according to the second embodiment, and also illustrating the display region DA, the formation region of the second electrode 25 including the extending portion 25′, and the formation region of the cap layer 26 in the active matrix substrate 41. Note that the active matrix substrate 41 illustrated in FIG. 9 is configured in consideration of a case where the function layer 24 is formed using the mask 32 illustrated in FIG. 8.

As illustrated in FIG. 9, a notched portion is provided in the display region DA of the active matrix substrate 41. Then, an end portion 25EL of the extending portion 25′ includes a first notched region KGP, of the extending portion 25′, formed along the notched portion. The cap layer 26 is formed covering all of the first notched region KGP of the extending portion 25′.

Further, the extending portion 25′ includes second notched regions RGP formed corresponding to corner portions of the display region DA. The cap layer 26 is formed covering the second notched regions RGP of the extending portion 25′.

In the active matrix substrate 41, the cap layer 26 does not cover the extending portion 25′ in regions other than the first notched region KGP of the extending portion 25′ and the second notched regions RGP of the extending portion 25′.

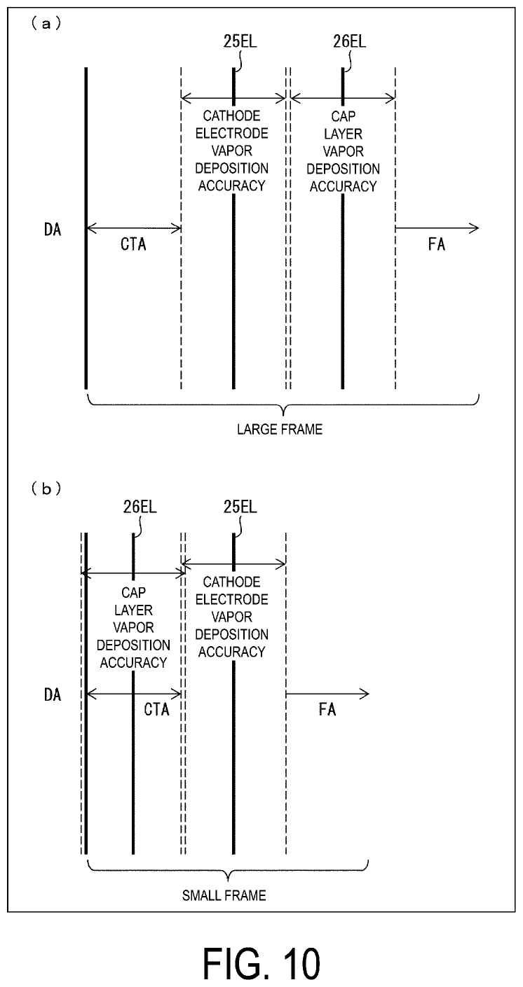

(a) of FIG. 10 is a diagram illustrating a region in which the frame region is large in the display device according to the second embodiment, and (b) of FIG. 10 is a diagram illustrating a region in which the frame region is small in the display device according to the second embodiment.

As illustrated in (a) of FIG. 10, when the end portion 25EL of the second electrode 25 (the cathode electrode) including the extending portion 25′ is positioned closer to the display region DA than the end portion 26EL of the cap layer (Cap layer) 26, the frame region becomes large since a contact region CTA needs to be separately secured. On the other hand, as illustrated in (b) of FIG. 10, when the end portion 25EL of the second electrode 25 (the cathode electrode) including the extending portion 25′ is positioned farther from the display region DA than the end portion 26EL of the cap layer (Cap layer) 26, the frame region becomes small since it is not necessary to separately secure the contact region CTA. Thus, in the active matrix substrate 41 illustrated in FIG. 9, a region in which the end portion 25EL of the second electrode 25 (the cathode electrode) including the extending portion 25′ is positioned closer to the display region DA than the end portion 26EL of the cap layer (Cap layer) 26, as illustrated in (a) of FIG. 10, is reduced, and a region in which the end portion 25EL of the second electrode 25 (the cathode electrode) including the extending portion 25′ is positioned farther from the display region DA than the end portion 26EL of the cap layer (Cap layer) 26, as illustrated in (b) of FIG. 10, is increased. As a result, the frame narrowing of the display device can be achieved.

In the present embodiment, the cap layer 26 covers all of the first notched region KGP of the extending portion 25′ and the four second notched regions RGP of the extending portion 25′, but no such limitation is intended, and the cap layer 26 may cover only the first notched region KGP of the extending portion 25′, or may cover only one or more of the four second notched regions RGP of the extending portion 25′.

### Supplement

### First Aspect

A display device includes a display region in which a plurality of light-emitting elements are disposed, a frame region surrounding the display region, and a sealing layer, each of the light-emitting elements being provided with a first electrode, a second electrode formed above the first electrode, and a function layer formed between the first electrode and the second electrode. The second electrode includes an extending portion extending from the display region to the frame region, and overlaps all of the display region. A cap layer is provided above the extending portion to overlap at least part of an end portion of the extending portion, and the cap layer overlaps all of the display region. The sealing layer overlaps all of the second electrode and all of the cap layer.

### Second Aspect

In the display device according to the first aspect, a notched portion is provided in the display region, the extending portion includes a first notched region formed along the notched portion, and the cap layer is formed covering all of the first notched region.

### Third Aspect

In the display device according to the first or second aspect, the extending portion includes a second notched region formed corresponding to a corner portion of the display region, and the cap layer is formed covering at least part of the second notched region.

### Fourth Aspect

In the display device according to any one of the first to third aspects, the cap layer overlaps all of the second electrode including the extending portion.

### Fifth Aspect

The display device according to any one of the first to third aspects includes a drive circuit configured to drive the plurality of light-emitting elements. On a side, which is a side of the drive circuit, of the extending portion, the end portion of the extending portion is positioned closer to the drive circuit than an end portion of the cap layer.

### Sixth Aspect

The display device according to any one of the first to fifth aspects, the cap layer is an inorganic film.

### Seventh Aspect

In the display device according to the sixth aspect, the inorganic film is a LiF film.

### Eighth Aspect

The display device according to any one of the first to fifth aspects, the cap layer is an organic film.

### Ninth Aspect

In the display device according to the eighth aspect, the organic film is a film containing an aromatic hydrocarbon.

### Tenth Aspect

The display device according to any one of the first to fifth aspects, the cap layer is a layered body of an organic film and an inorganic film.

### Eleventh Aspect

In the display device according to the tenth aspect, the organic film is a film containing an aromatic hydrocarbon, and the inorganic film is a LiF film.

### Twelfth Aspect

In the display device according to the tenth or eleventh aspect, a refractive index of the organic film in a visible light region is greater than a refractive index of the inorganic film in the visible light region.

### Thirteenth Aspect

In the display device according to the twelfth aspect, the refractive index of the organic film in the visible light region is from 1.8 to 2.1, and the refractive index of the inorganic film in the visible light region is from 1.2 to 1.3.

### Fourteenth Aspect

In the display device according to any one of the tenth to thirteenth aspect, a film thickness of the organic film is greater than a film thickness of the inorganic film.

### Fifteenth Aspect

In the display device according to the fourteenth aspect, the film thickness of the organic film is from 50 nm to 100 nm, and the film thickness of the inorganic film is from 10 nm to 30 nm.

### Additional Items

The present invention is not limited to each of the embodiments described above, and various modifications may be made within the scope of the claims. Embodiments obtained by appropriately combining technical approaches disclosed in each of the different embodiments also fall within the technical scope of the present invention. Furthermore, novel technical features can be formed by combining the technical approaches disclosed in the embodiments.

### INDUSTRIAL APPLICABILITY

The present invention can be utilized for a display device.

### REFERENCE SIGNS LIST

1 Display device
4 Active matrix substrate
5 Light-emitting element
6 Sealing layer
22 First electrode
22′ Lead portion
24 Function layer
25 Second electrode
25EL End portion (of extending portion)
25′ Extending portion
26 Cap layer
26EL End portion (of cap layer)
30 Mask
31 Mask
32 Mask
40 Active matrix substrate
40′ Active matrix substrate
41 Active matrix substrate
50 Drive circuit
DA Display region
NA Frame region
FK Mask opening
HK Mask recess
FEA Mask opening formation region
HEA Mask recess formation region
CON2 Contaminant
DRP Side on drive circuit side
KGP First notched region
RGP Second notched region

1. (canceled)

2. A display device including a display region in which a plurality of light-emitting elements are disposed, a frame region surrounding the display region, and a sealing layer, each of the light-emitting elements being provided with a first electrode, a second electrode formed above the first electrode, and a function layer formed between the first electrode and the second electrode,
wherein the second electrode includes an extending portion extending from the display region to the frame region, and overlaps all of the display region,
a cap layer is provided above the extending portion to overlap at least part of an end portion of the extending portion,
the cap layer overlaps all of the display region, and
the sealing layer overlaps all of the second electrode and all of the cap layer,
wherein a notched portion is provided in the display region,
the extending portion includes a first notched region formed along the notched portion, and
the cap layer is formed covering all of the first notched region.

3. The display device according to claim 1,
wherein the extending portion includes a second notched region formed corresponding to a corner portion of the display region, and
the cap layer is formed covering at least part of the second notched region.

4. The display device according to claim 2,
wherein the cap layer overlaps all of the second electrode including the extending portion.

5. The display device according to claim 2, comprising:
a drive circuit configured to drive the plurality of light-emitting elements,
wherein, on a side, which is a side of the drive circuit, of the extending portion, the end portion of the extending portion is positioned closer to the drive circuit than an end portion of the cap layer.

6. The display device according to claim 2,
wherein the cap layer is an inorganic film.

7. The display device according to claim 6,
wherein the inorganic film is a LiF film.

8. The display device according to claim 2,
wherein the cap layer is an organic film.

9. The display device according to claim 8,
wherein the organic film is a film containing an aromatic hydrocarbon.

10. The display device according to claim 2,
wherein the cap layer is a layered body of an organic film and an inorganic film.

11. The display device according to claim 10,
wherein the organic film is a film containing an aromatic hydrocarbon, and
the inorganic film is a LiF film.

12. The display device according to claim 10,
wherein a refractive index of the organic film in a visible light region is greater than a refractive index of the inorganic film in the visible light region.

13. The display device according to claim 12,
wherein the refractive index of the organic film in the visible light region is from 1.8 to 2.1, and
the refractive index of the inorganic film in the visible light region is from 1.2 to 1.3.

14. The display device according to claim 10,
wherein a film thickness of the organic film is greater than a film thickness of the inorganic film.

15. The display device according to claim 14,
wherein the film thickness of the organic film is from 50 nm to 100 nm, and the film thickness of the inorganic film is from 10 nm to 30 nm.
